(19) United States
(12) Patent Application Publication
(10) Pub. No.: US 2025/0172596 A1
(43) Pub. Date: May 29, 2025

(54) HIGH-PRECISION PULSE WIDTH MEASUREMENT CIRCUIT AND MEASUREMENT METHOD

(71) Applicant: HUNAN GREAT-LEO MICROELECTRONICS CO., LTD., Hunan (CN)

(72) Inventors: Hu CHEN, Hunan (CN); Xiao GONG, Hunan (CN); Xianghong LI, Hunan (CN)

(73) Assignee: HUNAN GREAT-LEO MICROELECTRONICS CO., LTD., Hunan (CN)

(21) Appl. No.: 18/842,050

(22) PCT Filed: Feb. 24, 2023
(86) PCT No.: PCT/CN2023/078215

§ 371 Date: Aug. 28, 2024

(30) Foreign Application Priority Data
Feb. 28, 2022 (CN) 202210191682.3

(51) Int. Cl. G01R 29/02

(52) U.S. Cl. CPC G01R 29/023

(57) ABSTRACT

A high-precision pulse width measurement circuit includes a sampling clock and calibration clock circuit, a sampling circuit, and a calibration circuit. The sampling clock and calibration clock circuit includes a group of delay units and a clock frequency divider, wherein each of the delay units is used for outputting a periodic sampling clock signal HRCLK, and the clock frequency divider is used for generating, according to the sampling clock signal HRCLK, a low-frequency clock signal CALCLK for sampling precision calibration. The sampling circuit, only working in an HRCLK clock domain, includes a counter HRCNT, four capture registers HRCAP1-HRCAP4, an edge detection circuit, and an interrupt control circuit. The calibration circuit includes counters CALCNT and SYSCNT, bit capture registers CALCAP and SYSCAP, a bit register CALPRD and a comparator.

### CROSS-REFERENCE OF RELATED APPLICATION

The application is based on and claims priority to Chinese Patent Application No. 202210191682.3, entitled “High-Precision Pulse Width Measurement Circuit and Measurement Method”, filed on Feb. 28, 2022, which is incorporated herein by reference in its entirety as one part of the application.

### TECHNICAL FIELD

The invention mainly relates to the technical field of digital pulse signal detection, and particularly relates to a high-precision pulse width measurement circuit and a measurement method.

### DESCRIPTION OF RELATED ART

High-precision digital pulse signal width measurement is widely applied to precision instruments, sonar, robot servos, switching power supplies, power devices, touch screens and other devices to realize pulse sequence period/duty cycle measurement, instantaneous velocity measurement, trans-isolation boundary voltage measurement, distance/sonar measurement and touch perception.

Generally, digital pulse signal width measurement is implemented by expressing the width of a pulse signal as a real number including an integer part and a decimal part using a sampling clock HRCLK (frequency: fHRCLK) with one clock period as a reference unit. Referring to FIG. 1, the relation between the width λ of the pulse signal, fHRCLK, μ, α and β is as follows:

$$λ = ( μ - α - β ) \times 1 / fHRCLK , \\ μ is a positive integer , α and β are decimals \qquad ( 1 )$$

Generally, the frequency fHRCLK of the sampling clock HRCLK is significantly higher than the operating frequency fSYSCLK of a global system clock SYSCLK in a system to fulfill the purpose of high-precision pulse width sampling and measurement. If the frequency fHRCLK of the sampling clock HRCLK is high enough, the measurement precision will satisfy requirements, and α and β in formula (1) can be ignored, that is:

$$λ \approx μ \times 1 / fHRCLK , μ is a positive integer \qquad ( 2 )$$

The technical solution in U.S. Pat. No. 8,384,440B2 discloses a measurement method, which has high precision and does not need a high-frequency sampling clock. However, this method limits the operating range of the sampling clock, and the use of a capture delay chain and the periodic execution of a software calibration program increase software and hardware expenditures.

In addition, Chinese Patent Application No. CN202010404936.6 discloses a circuit and method for width measurement of digital pulse signals. The circuit comprises: a sampling clock, used to drive all registers in the circuit; an edge detection and interrupt control unit, used to detect a rising edge and a falling edge of a pulse signal on an input pin to control signal collection; an integer encoding unit comprising a counter and registers and used to measure an integer part of the width of a high or low level on the input pin with one period 1/f of the sampling clock as a reference unit; a signal capture chain, used to sample an output level of each delay cell DLL; a decimal encoding unit, used to find out and record the position of the pulse edge propagating on the signal capture chain; and a calibration control unit, used to perform calibration. The circuit is implemented based on the circuit and has the advantages of high precision, simple structure, and small resource expenditure. However, the circuit in this scheme also comprises a delay chain, leading to a large hardware expenditure.

### SUMMARY

In view of the technical problems existing in the prior art, the technical issue to be settled by the invention is to provide a high-precision pulse width measurement circuit and a measurement method, which are simple in principle, easy to operate, small in software and hardware expenditure and high in measurement precision.

To fulfill the above purpose, the embodiments of the invention adopt the following technical solution:

A high-precision pulse width measurement circuit, comprising:
a sampling clock and calibration clock circuit, comprising a group of delay units and a clock frequency divider, wherein each of the delay units is used for outputting a periodic sampling clock signal HRCLK, and the clock frequency divider is used for generating, according to the sampling clock signal HRCLK, a low-frequency clock signal CALCLK for sampling precision calibration;
a sampling circuit, only working in an clock domain of the sampling clock signal HRCLK and comprising a counter HRCNT, four capture registers HRCAP1-HRCAP4, and edge detection and interrupt control circuits; and
a calibration circuit, comprising counters CALCNT and SYSCNT, bit capture registers CALCAP and SYSCAP, a bit register CALPRD and a comparator, wherein after setting the calibration enable signal CALEN=1, the counters CALCNT and SYSCNT start to count from 0; when a value of the counter SYSCNT is equal to a value of the bit register CALPRD, the comparator generates a high-level pulse CALDONE indicating the completion of one calibration period, and values of the counters CALCNT and SYSCNT are triggered to be loaded into the bit capture registers CALCAP and SYSCAP respectively.

As a further improvement of the circuit of the present invention, the group of delay units DLL[1]-DLL[i] form an oscillator when a control signal HREN=1, DLL[i] has a phase reversing function, and assume a delay generated when a signal passes through one delay unit is δ, the oscillator outputs a periodic sampling clock signal HRCLK after becoming stable.

As a further improvement of the circuit of the present invention, the clock frequency divider is used for performing N-times frequency division on the sampling clock signal HRCLK to generate the low-frequency clock signal CALCLK for sampling precision calibration.

As a further improvement of the circuit of the present invention, in the sampling circuit, the counter HRCNT starts to count from 0 after the circuit is reset; and when the edge detection circuit detects an edge of an input pulse signal INPUT, values of the counter HRCNT are sequentially loaded into the capture registers HRCAP1-HRCAP4.

As a further improvement of the circuit of the present invention, the values of the counter HRCNT are sequentially loaded into the capture registers HRCAP1-HRCAP4 as follows: when a first edge of the input pulse signal INPUT arrives, the value of the counter HRCNT is loaded into the capture register HRCAP1; when a second edge of the input pulse signal INPUT arrives, the value of the counter HRCNT is loaded into the capture register HRCAP2; when a third edge of the input pulse signal INPUT arrives, the value of the counter HRCNT is loaded into the capture register HRCAP3; when a fourth edge of the input pulse signal INPUT arrives, the value of the counter HRCNT is loaded into the capture register HRCAP4; and when a fifth edge of the input pulse signal INPUT arrives, the operation performed when the first edge of the input pulse signal INPUT arrives is repeated.

As a further improvement of the circuit of the present invention, the interrupt control circuit is used for a sampling interrupt event SAPINT arrive after a set number of edges of the input pulse signal INPUT arrive and informing software to read values in the capture registers HRCAP1-HRCAP4 to complete subsequent processing.

As a further improvement of the circuit of the present invention, the counter CALCNT and the bit capture register CALCAP work in a clock domain of the low-frequency clock signal CALCLK, and the counter SYSCNT and the bit capture register SYSCAP work in a system clock domain SYSCLK.

The invention further provides a measurement method based on the high-precision pulse width measurement circuit, comprises the following steps:
S1: resetting the capture counter HRCNT: after the counter HRCNT is reset, driving, by the clock HRCLK, the counter HRCNT to count from 0;
S2: loading to the capture register HRCAP1: after the counter HRCNT is reset, loading a current value of the counter HRCNT to the capture register HRCAP1 when the edge detection circuit detects a first edge of the input pulse signal INPUT;
S3: loading to the capture register HRCAP2: loading a current value of the counter HRCNT to the capture register HRCAP2 when the edge detection circuit detects a second edge of the input pulse signal INPUT;
S4: loading to the capture register HRCAP3: loading a current value of the counter HRCNT to the capture register HRCAP3 when the edge detection circuit detects a third edge of the input pulse signal INPUT;
S5: loading to the capture register HRCAP4: loading a current value of the counter HRCNT to the capture register HRCAP4 when the edge detection circuit detects a fourth edge of the input pulse signal INPUT; and
S6: interrupt processing: after the sampling interrupt event arrives, reading, by an interrupt service routine reads, the values in the capture registers HRCAP1-HRCAP4, and calculating an actual pulse width, wherein the interrupt service routine generally resets or zeros the counter HRCNT to allow the circuit to return to S1 to start a new sampling period.

As a further improvement of the circuit of the present invention, wherein in S1, the counter HRCNT is reset when the circuit is powered on or by software.

As a further improvement of the circuit of the present invention, wherein in S5, in the interrupt control circuit, one the sampling interrupt event is triggered after four events of the input pulse signal INPUT arrive, and after the current value of the counter HRCNT is loaded into the capture register HRCAP4, one sampling interrupt event is triggered to inform software to read the values in the capture registers HRCAP1-HRCAP4 and complete subsequent processing.

As a further improvement of the circuit of the present invention, further comprising a process of measurement precision calibration, which comprises the following steps:
S101: initialization: setting the calibration enable signal CALEN=0, zeroing the counters CALCNT and SYSCNT, and zeroing the bit capture registers CALCAP, SYSCAP and the bit register CALPRD;
S102: enabling the calibration circuit: setting the calibration enable signal CALEN=1 to enable the calibration circuit;
S103: starting calibration counting: setting a control bit CALSTART=1 to start calibration counting, and driving the counters CALCNT and SYSCNT by clocks CALCLK and SYSCLK to count from 0;
S104: saving calibration values; when the comparator detects that a value of the counter SYSCNT is equal to a value in the bit register CALPRD, generating a pulse signal CALDONE, loading values the counters CALCNT and SYSCNT into the bit capture registers CALCAP and SYSCAP, and generating a calibration completion interrupt CALINT to inform the software to read the values in the bit capture registers CALCAP and SYSCAP to complete subsequent processing; and
S105: interrupt processing: reading, by the interrupt service routine, the values in the bit capture registers CALCAP and SYSCAP to complete subsequent processing, and determining whether subsequent calibration needs to be performed; and if the subsequent calibration needs to be performed, returning to S103.

Compared with the prior art, the invention has the following advantages:

1. The high-precision pulse width measurement circuit and the measurement method adopts a sampling clock circuit which has a simple structure and high portability and are free of a delay chain with a high hardware resource expenditure, thus having the characteristics of being simple, visual, easy to use, and small in software and hardware expenditure.

2. By implementing the high-precision pulse width measurement circuit and the measurement method, the measurement precision can reach 100 psl; moreover, the measurement precision can be calibrated periodically according to the change of the actual operating environment (such as temperature and operating voltage).

### BRIEF DESCRIPTION OF THE DRAWINGS

FIG. 1 is a schematic diagram of digital pulse signal measurement.

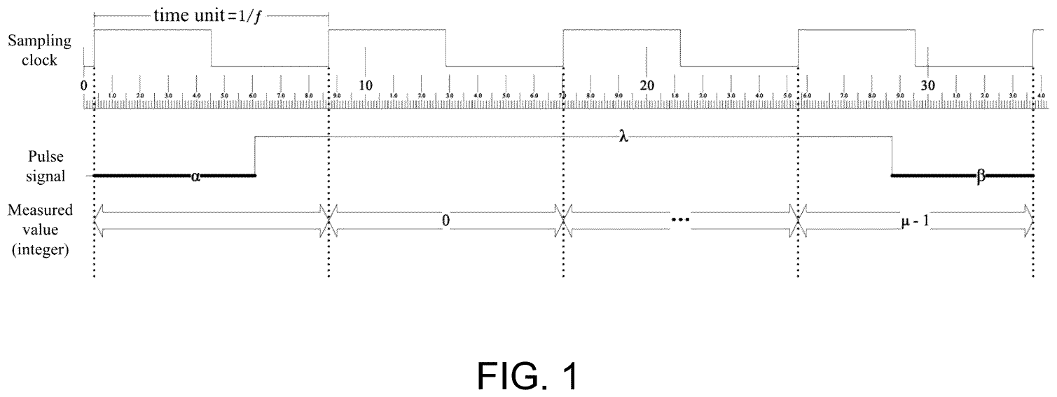

FIG. 2 is a schematic diagram of the structure and principle of a sampling clock and calibration clock circuit according to one specific application example of the invention.

FIG. 3 is a schematic diagram of the structure and principle of a sampling circuit according to one specific application example of the invention.

FIG. 4 is a schematic diagram of the structure and principle of a calibration circuit according to one specific application example of the invention.

FIG. 5 is a schematic flow diagram of pulse width measurement according to one specific application example of the invention.

FIG. 6 is a schematic diagram of the principle of pulse width measurement according to one specific application example of the invention.

FIG. 7 is a schematic flow diagram of measurement precision calibration according to one specific application example of the invention.

### DESCRIPTION OF THE EMBODIMENTS

The invention is described in further detail below in conjunction with accompanying drawings and specific embodiments.

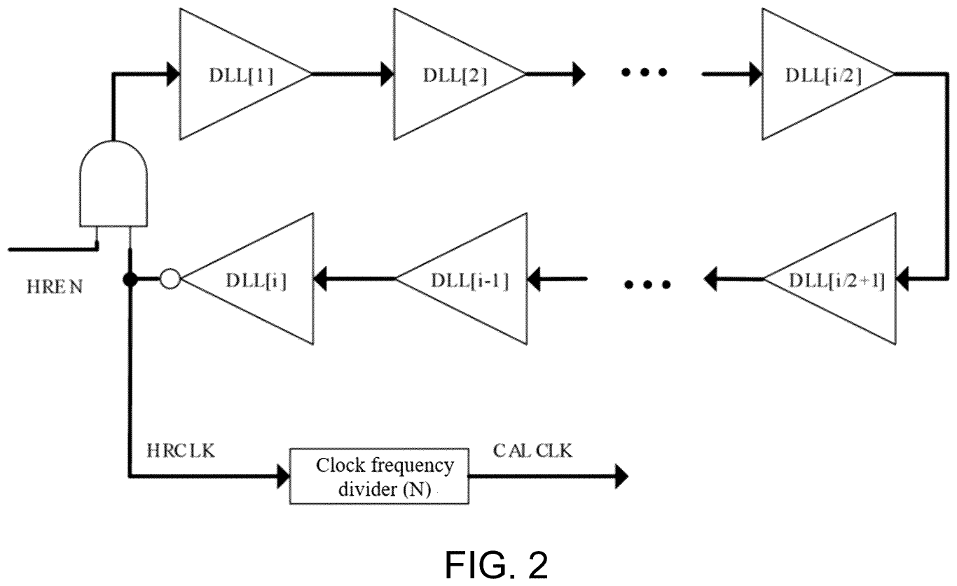

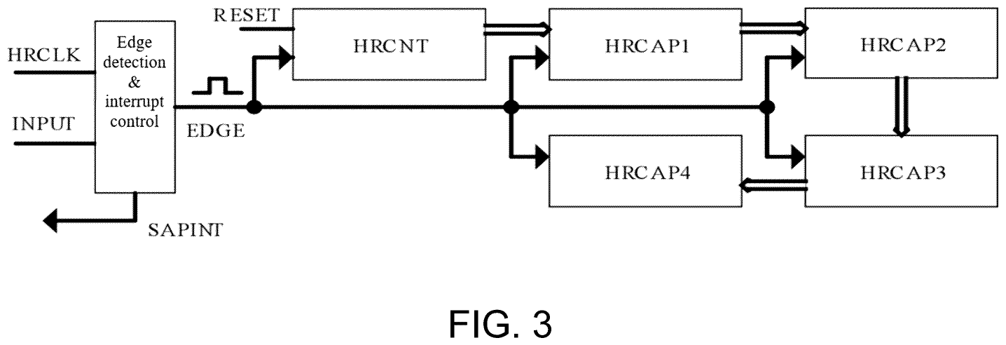

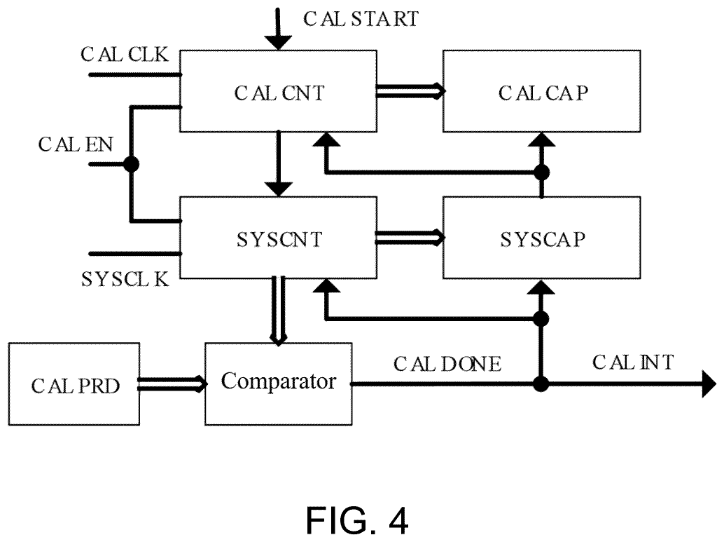

As shown in FIGS. 2-6, the invention provides a high-precision pulse width measurement circuit, comprising:
a sampling clock and calibration clock circuit, comprising a group of delay units and a clock frequency divider, wherein each of the delay units is used for outputting a periodic sampling clock signal HRCLK, and the clock frequency divider is used for generating, according to the sampling clock signal HRCLK, a low-frequency clock signal CALCLK for sampling precision calibration;
a sampling circuit, only working in a clock domain of the sampling clock signal HRCLK and comprising a 32-bit counter HRCNT, four 32-bit capture registers HRCAP1-HRCAP4, and edge detection and interrupt control circuits; and
a calibration circuit, comprising 32-bit counters CALCNT and SYSCNT, 32-bit capture registers CALCAP and SYSCAP, a 32-bit register CALPRD and a comparator, wherein after setting the calibration enable signal CALEN=1, the counters CALCNT and SYSCNT start to count from 0; when a value of the counter SYSCNT is equal to a value of the bit register CALPRD, the comparator generates a high-level pulse CALDONE indicating the completion of one calibration period, and values of the counters CALCNT and SYSCNT are triggered to be loaded into the bit capture registers CALCAP and SYSCAP respectively.

In one specific application embodiment, the group of delay units DLL[1]-DLL[i] form an oscillator when a control signal HREN=1. Wherein, DLL[i] has a phase reversing function. Assume a delay generated when a signal passes through one delay unit is δ, the oscillator outputs a periodic sampling clock signal HRCLK after becoming stable. The relation between a period THRCLK of a sampling clock signal HRCLK, the delay δ of the delay units, and the number of the delay units is as follows:

$$THRCLK = 2 \times i \times δ , i is an even number \qquad ( 3 )$$

The clock frequency divider is used for performing N-times frequency division on the sampling clock signal HRCLK to generate the low-frequency clock signal CALCLK for sampling precision calibration.

The relation between a period of a calibration clock CALCLK and the period of the sampling clock signal HRCLK is as follows:

$$TCALCLK = THRCLK \times N . N is a positive integer \qquad ( 4 )$$

In one specific application embodiment, in the sampling circuit, the counter HRCNT starts to count from 0 after the circuit is reset. When the edge detection circuit detects an edge (a rising edge or a falling edge) of an input pulse signal INPUT, values of the counter HRCNT are sequentially loaded into the capture registers HRCAP1-HRCAP4.

Preferably, the values of the counter HRCNT are sequentially loaded into the capture registers HRCAP1-HRCAP4 as follows: when a first edge of the input pulse signal INPUT arrives, HRCNT→HRCAP1; when a second edge of the input pulse signal INPUT arrives, HRCNT→HRCAP2; when a third edge of the input pulse signal INPUT arrives, HRCNT→HRCAP3; when a fourth edge of the input pulse signal INPUT arrives, HRCNT→HRCAP4; and when a fifth edge of the input pulse signal INPUT arrives, the operation performed when the first edge arrives is repeated, and so on.

The interrupt control circuit is used for triggering a sampling interrupt event SAPINT after a set number of edges of the input pulse signal INPUT arrive and informing software to read values in the registers HRCAP1-HRCAP4 to complete subsequent processing.

In one specific application embodiment, the counter CALCNT and the bit capture register CALCAP work in a clock domain of the low-frequency clock signal CALCLK, and the counter SYSCNT and the capture register SYSCAP work in a system clock domain SYSCLK.

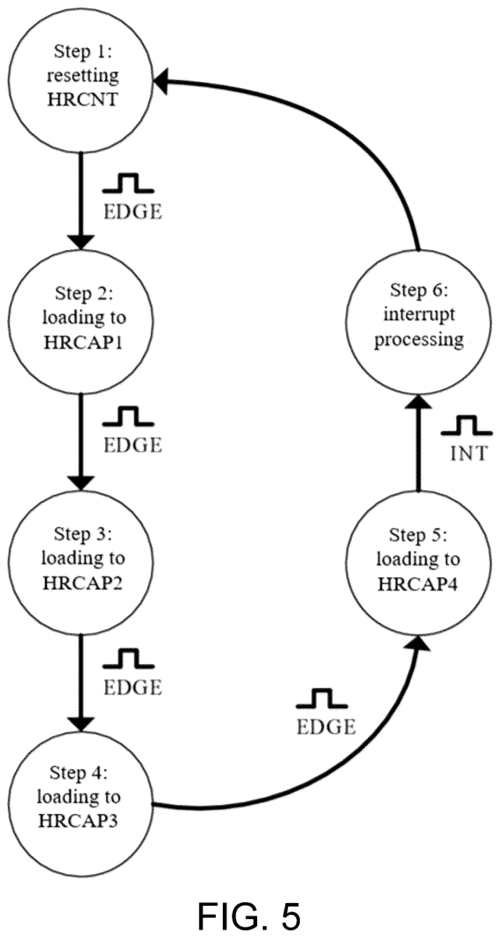

Referring to FIG. 5, the invention further provides a measurement method based on the high-precision pulse width measurement circuit. Assume the interrupt control circuit triggers a sampling interrupt after four events (edges) of the input pulse signal INPUT arrive, the measurement method comprises the following steps:
S1: resetting the counter HRCNT when the circuit is powered on or by software; and after the counter HRCNT is reset, driving, by the clock HRCLK, the counter HRCNT to count from 0;
S2: loading to the capture register HRCAP1: after the counter HRCNT is reset, loading a current value of the counter HRCNT to the capture register HRCAP1 when the edge detection circuit detects a first edge of the input pulse signal INPUT;
S3: loading to the capture register HRCAP2: loading a current value of the counter HRCNT to the capture register HRCAP2 when the edge detection circuit detects a second edge of the input pulse signal INPUT;
S4: loading to the capture register HRCAP3: loading a current value of the counter HRCNT to the capture register HRCAP3 when the edge detection circuit detects a third edge of the input pulse signal INPUT;
S5: loading to the capture register HRCAP4: loading a current value of the counter HRCNT to the capture register HRCAP4 when the edge detection circuit detects a fourth edge of the input pulse signal INPUT, wherein because the interrupt control circuit triggers a sampling interrupt after four events (edges) of the input pulse signal INPUT arrive, after the current value of the counter HRCNT is loaded into the capture register HRCAP4, the sampling interrupt will be triggered to inform software to read values in the capture registers HRCAP1-HRCAP4 and complete subsequent processing; and
S6: interrupt processing: after the sampling interrupt event arrives, reading, by an interrupt service routine reads, the values in the capture registers HRCAP1-HRCAP4, and calculating an actual pulse width, wherein the interrupt service routine generally resets or zeros the counter HRCNT to allow the circuit to return to S1 to start a new sampling period.

It can be known from above that the pulse width measurement method comprises a process of pulse width sampling and a process of pulse width calculation, as shown in FIG. 5. Pulse width sampling is completed in S1-S5 by a hardware circuit, and pulse width calculation is performed in S6 by software.

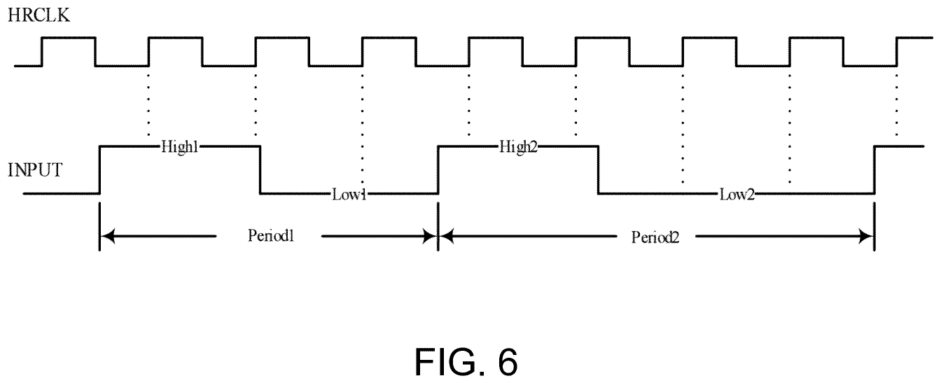

A pulse on an input pin INPUT is shown in FIG. 6, a sampling interrupt is triggered after four events (edges) of the input pulse signal INPUT arrive, and the pulse width is calculated by software as follows:

$${T}_{High 1} = ( HRCAP 2 - HRCAP 1 ) \times {T}_{HRCLK} \qquad ( 5 )$$

$${T}_{Low 1} = ( HRCAP 3 - HRCAP 2 ) \times {T}_{HRCLK} \qquad ( 6 )$$

$${T}_{Period 1} = ( HRCAP 3 - HRCAP 1 ) \times {T}_{HRCLK} \qquad ( 7 )$$

$${T}_{High 2} = ( HRCAP 4 - HRCAP 2 ) \times {T}_{HRCLK} \qquad ( 8 )$$

$${T}_{Low 2} = ( HRCAP 3 - HRCAP 2 ) \times {T}_{HRCLK} \qquad ( 9 )$$

$${T}_{Period 2} = ( HRCAP 4 - HRCAP 2 ) \times {T}_{HRCLK} \qquad ( 10 )$$

THRCLK in formulas (5)-(10) is obtained according to formulas (11)-(13).

Generally, because the delay δ of the delay units varies within a wide range with temperature and operating voltage, the period of the sampling clock HRCLK needs to be calibrated to obtain an accurate pulse width measurement result. Because the system work clock SYSCLK is generally produced by specified PLL and has high stability, a scale factor ScaleFactor can be obtained by giving the period T_{SYSCLK} of the system work clock SYSCLK and calibrating the relation between the periods of the two clocks CALCLK and SYSCLK, and then the period THRCLK of the sampling clock HRCLK can be determined accurately.

$$ScaleFactor = SYSCAP / CALCAP \qquad ( 11 )$$

$${T}_{CALCLK} = ScaleFactor \times {T}_{SYSCLK} \qquad ( 12 )$$

$${T}_{HRCLK} = ScaleFactor \times {T}_{SYSCLK} / N \qquad ( 13 )$$

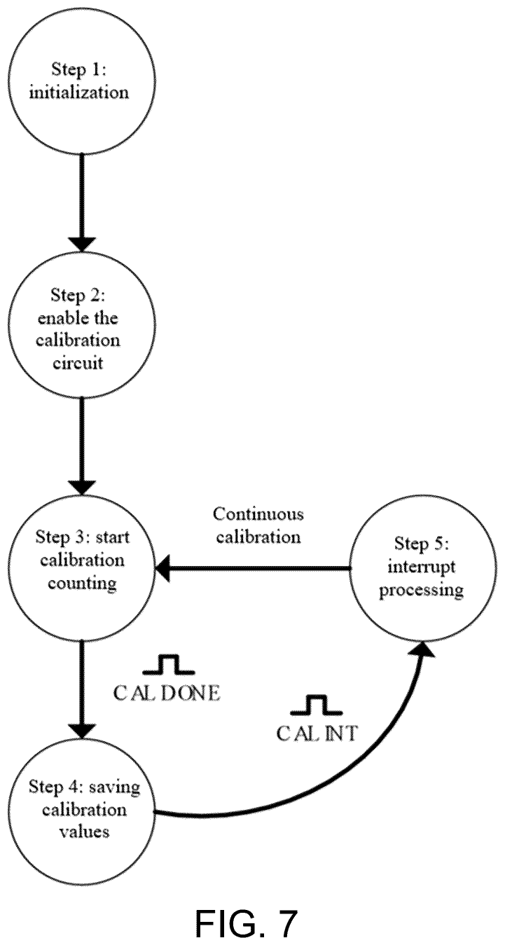

Referring to FIG. 7, as a preferred embodiment, the measurement method provided by the invention further comprises a process of measurement precision calibration, which comprises the following steps:
S101: initialization: setting the calibration enable signal CALEN=0, zeroing the counters CALCNT and SYSCNT, and zeroing the bit capture registers CALCAP, SYSCAP and the bit register CALPRD;
S102: enabling the calibration circuit: setting the calibration enable signal CALEN=1 to enable the calibration circuit;
S103: starting calibration counting: setting a control bit CALSTART=1 to start calibration counting, and driving, by the clocks CALCLK and SYSCLK, the counters CALCNT and SYSCNT to count from 0;
S104: saving calibration values: when the comparator detects that a value of the counter SYSCNT is equal to a value in the bit register CALPRD, generating a pulse signal CALDONE, loading values in the counters CALCNT and SYSCNT into the bit capture registers CALCAP and SYSCAP, and generating a calibration completion interrupt event CALINT to inform the software to read the values in the bit capture registers CALCAP and SYSCAP to complete subsequent processing; and
S105: interrupt processing: reading, by the interrupt service routine, the values in the bit capture registers CALCAP and SYSCAP to complete subsequent processing, and determining whether subsequent calibration needs to be performed; and if the subsequent calibration needs to be performed, returning to S103.

The calibration circuit also comprises a continuous calibration control bit CALCON. If CALCON=1 is set in S102 or S103, the calibration circuit automatically performs S103 after S105 is completed, so as to start the next calibration process, and the control bit CALSTART does not need to be set anymore.

The period T_{SYSCLK} of the system clock SYSCLK is given, the interrupt service routine calculates the relation between the period of the calibration clock CALCLK, the period of the sampling clock HRCLK and the period of the system clock SYSCLK according to formulas (11)-(13).

It can be known from the above that the measurement precision calibration process actually comprises a process of calibration counting and a process of precision calculation, wherein calibration counting is completed in S101-S104 by a hardware circuit, and calibration counting is performed in S105 by software.

The preferred embodiments of the invention are described above, but the protection scope of the invention is not limited to the above embodiment. All technical solutions based on the concept of the invention should fall within the protection scope of the invention. It should be noted that some improvements and embellishments made by those ordinarily skilled in the art without departing from the principle of the invention should also fall within the protection scope of the invention.

1. A high-precision pulse width measurement circuit, comprising:
a sampling clock and calibration clock circuit, comprising a group of delay units and a clock frequency divider, wherein each of the delay units is used for outputting a periodic sampling clock signal HRCLK, and the clock frequency divider is used for generating, according to the sampling clock signal HRCLK, a low-frequency clock signal CALCLK for sampling precision calibration;
a sampling circuit, only working in a clock domain of the sampling clock signal HRCLK and comprising a counter HRCNT, four capture registers HRCAP1-HRCAP4, an edge detection circuit, and an interrupt control circuit; and
a calibration circuit, comprising counters CALCNT and SYSCNT, bit capture registers CALCAP and SYSCAP, a bit register CALPRD and a comparator, wherein after setting a calibration enable signal CALEN=1, the counters CALCNT and SYSCNT start to count from 0; when a value of the counter SYSCNT is equal to a value of the bit register CALPRD, the comparator generates a high-level pulse CALDONE indicating the completion of one calibration period, and values of the counters CALCNT and SYSCNT are triggered to be loaded into the bit capture registers CALCAP and SYSCAP, respectively.

2. The high-precision pulse width measurement circuit according to claim 1, wherein the group of delay units DLL[1]-DLL[i] form an oscillator when a control signal HREN=1, DLL[i] has a phase reversing function, and assume a delay generated when a signal passes through one delay unit is δ, the oscillator outputs a periodic sampling clock signal HRCLK after becoming stable.

3. The high-precision pulse width measurement circuit according to claim 2, wherein the clock frequency divider is used for performing N-times frequency division on the sampling clock signal HRCLK to generate the low-frequency clock signal CALCLK for sampling precision calibration.

4. The high-precision pulse width measurement circuit according to claim 1, wherein in the sampling circuit, the counter HRCNT starts to count from 0 after the sampling circuit is reset; and when the edge detection circuit detects an edge of an input pulse signal INPUT, values of the counter HRCNT are sequentially loaded into the capture registers HRCAP1-HRCAP4.

5. The high-precision pulse width measurement circuit according to claim 4, wherein the values of the counter HRCNT are sequentially loaded into the capture registers HRCAP1-HRCAP4 as follows: when a first edge of the input pulse signal INPUT arrives, the value of the counter HRCNT is loaded into the capture register HRCAP1;
when a second edge of the input pulse signal INPUT arrives, the value of the counter HRCNT is loaded into the capture registerHRCAP2;
when a third edge of the input pulse signal INPUT arrives, the value of the counter HRCNT is loaded into the capture registerHRCAP3;
when a fourth edge of the input pulse signal INPUT arrives, the value of the counter HRCNT is loaded into the capture register HRCAP4; and
when a fifth edge of the input pulse signal INPUT arrives, the operation performed when the first edge of the input pulse signal INPUT arrives is repeated.

6. The high-precision pulse width measurement circuit according to claim 1, wherein the counter CALCNT and the bit capture register CALCAP work in a clock domain of the low-frequency clock signal CALCLK, and the counter SYSCNT and the bit capture register SYSCAP work in a system clock domain SYSCLK.

7. A measurement method based on the high-precision pulse width measurement circuit according to claim 1, comprising the following steps:
S1: resetting the counter HRCNT; after the counter HRCNT is reset, driving, by a clock HRCLK, the counter HRCNT to count from 0;
S2: loading to the capture register HRCAP1: after the counter HRCNT is reset, loading a current value of the counter HRCNT to the capture register HRCAP1 when the edge detection circuit detects a first edge of the input pulse signal INPUT;
S3: loading to the capture register HRCAP2: loading a current value of the counter HRCNT to the capture register HRCAP2 when the edge detection circuit detects a second edge of the input pulse signal INPUT;
S4: loading to the capture register HRCAP3: loading a current value of the counter HRCNT to the capture register HRCAP3 when the edge detection circuit detects a third edge of the input pulse signal INPUT;
S5: loading to the capture register HRCAP4: loading a current value of the counter HRCNT to the capture register HRCAP4 when the edge detection circuit detects a fourth edge of the input pulse signal INPUT; and
S6: interrupt processing: after a sampling interrupt event arrives, reading, by an interrupt service routine, the values in the capture registers HRCAP1-HRCAP4 and calculating an actual pulse width, wherein the interrupt service routine resets or zeros the counter HRCNT to allow the sampling circuit to return to S1 to start a new sampling period.

8. The measurement method according to claim 7, wherein in S1, the counter HRCNT is reset when the sampling circuit is powered on or by software.

9. The measurement method according to claim 7, wherein in S5, in the interrupt control circuit, one sampling interrupt event is triggered after four events of the input pulse signal INPUT arrive, and after the current value of the counter HRCNT is loaded into the capture register HRCAP4, one sampling interrupt event is triggered to inform software to read the values in the capture registers HRCAP1-HRCAP4 and complete subsequent processing.

10. The measurement method according to claim 7, further comprising a process of measurement precision calibration, which comprises the following steps:
S101: initialization: setting the calibration enable signal CALEN=0, zeroing the counters CALCNT and SYSCNT, and zeroing the bit capture registers CALCAP, SYSCAP and the bit register CALPRD;
S102: enabling the calibration circuit: setting the calibration enable signal CALEN=1 to enable the calibration circuit;
S103: starting calibration counting: setting a control bit CALSTART=1 to start calibration counting, and driving the counters CALCNT and SYSCNT by clocks CALCLK and SYSCLK to count from 0;
S104: saving calibration values: when the comparator detects that a value of the counter SYSCNT is equal to a value in the bit register CALPRD, generating a pulse signal CALDONE, loading values the counters CALCNT and SYSCNT into the bit capture registers CALCAP and SYSCAP, and generating a calibration completion interrupt event CALINT to inform the software to read the values in the bit capture registers CALCAP and SYSCAP to complete subsequent processing; and
S105: interrupt processing: reading, by the interrupt service routine, the values in the bit capture registers CALCAP and SYSCAP to complete subsequent processing, and determining whether subsequent calibration needs to be performed; and if the subsequent calibration needs to be performed, returning to S103.
